(19) United States
(12) Patent Application Publication
(10) Pub. No.: US 2008/0067629 A1
(43) Pub. Date: Mar. 20, 2008

(54) Electrical Fuse Having Resistor Materials Of Different Thermal Stability

(75) Inventor: Katsura Miyashita, Naka-gun (JP)

Correspondence Address: BANNER & WITCOFF, LTD., 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 11/465,188

(22) Filed: Aug. 17, 2006

(51) Int. Cl. H01L 29/00

(52) U.S. Cl. 257/535

(57) ABSTRACT

An electrical fuse has a substrate and a resistor. The resistor has a first area and a second area embedded in the first area. The first area is formed of a first material and the second area is formed of a second material having a lower thermal stability than that of the first material. Because of the different thermal stabilities, the second area is more likely to rupture when a programming voltage is applied. The eFuse provides increased reliability and enables lower programming voltages to be used.

### FIELD OF THE INVENTION

The present invention is directed to electrical fuses (eFuses) and, more particularly, to eFuses employing resistors manufactured with materials of different thermal stabilities.

### DESCRIPTION OF RELATED ART

Electrical fuses (eFuses) have replaced laser fuses in many large scale integration (LSI) product chips due to several advantages, such as occupying less space on chips and increased flexibility in back-end integration schemes with a low-k dielectric. EFuses also are less prone to corrosion, crack, and splatter issues than are laser fuses.

Most eFuses are designed to change the value of a resistor by rupturing it. In general, sensing voltage and programming voltage are sufficiently high (e.g., 3.3 V) to rupture the resistor. As process technology has progressed to smaller and smaller geometries, maximum operating voltages have been scaled downward, making it more difficult to get power to eFuses. Also, it is usually desirable to minimize the amount of current required by the programming operation so that metallization power buses that deliver current to the eFuses do not need to be large.

One common difficulty encountered in programming eFuses when encountering significant voltage limitations, for example in sub-nanometer technologies, is providing enough power to reliably blow the fuse in a single programming pulse. Multiple programming pulses are sometimes required to achieve the desired resistance, rendering the eFuses less reliable and less efficient.

There remains a need for improved eFuses, particularly eFuses with improved reliability and which can be programmed with relatively low voltages.

### SUMMARY OF THE INVENTION

The present invention, according to one aspect, is directed to an electrical fuse (eFuse) having a resistor formed on a substrate. The resistor has a first material defining a first area and a second material defining a second area that is embedded in the first area. The second material has a lower thermal stability than that of the first area. When a programming voltage is applied, the resistor is more likely to rupture in the second area than in the first area.

In a first embodiment, an eFuse includes a resistor having a first area with metal silicide, e.g., nickel silicide, on polysilicon and a second embedded area with metal silicide on polysilicon germanium. The material present in the embedded area, e.g., nickel silicide germanium (NiSi_{(1-y)}Ge_{y}), is less thermally stable than the nickel silicide present in the outer portions. The eFuse is more likely to rupture in the second area upon application of a programming voltage due to the lower thermal stability of this material.

In a second embodiment, the eFuse includes a resistor having an outer portion of metal silicide, and an inner portion of polysilicon formed on a substrate and which extends less than the full depth of the metal silicide layer. The first area is defined by the thicker portions of the metal silicide, while the second area is defined by the thinner portion of the metal silicide overlying the polysilicon inner portion. The thin layer of metal silicide in this area is less thermally stable than the thicker areas of metal silicide in the adjacent areas. Therefore, the second area is more likely to rupture than the first area upon application of a programming voltage.

In a third embodiment, an eFuse has a two-metal resistor formed on a substrate. The resistor has an outer portion of a first metal, such as cobalt silicide, defining a first area and an inner portion of a second metal, such as nickel silicide, defining a second area. The thin inner portion is less thermally stable than the thicker outer portion. Therefore, the inner portion is more likely to rupture than the outer portion upon application of a programming voltage.

In a fourth embodiment, an eFuse is formed on a silicon-on-insulator substrate and has an outer portion formed of silicon and an inner portion formed of silicon germanium. A metal silicide layer is provided over the outer and inner portions, defining a first area of metal silicide on silicon and a second area of metal silicide germanium on silicon germanium. This material of the second area is less thermally stable than the metal silicide of the first area, and therefore more likely to rupture upon application of a programming voltage.

In a fifth embodiment, an eFuse has resistor formed on a silicon-on-insulator substrate. The resistor includes an outer portion formed of silicon and an inner portion formed of silicon germanium that is entirely surrounded by the silicon portion. A metal silicide layer is provided over the silicon, defining a first area of metal silicide on silicon and a second area of metal silicide on silicon on silicon germanium. The metal silicide of the second area, which has silicon germanium underneath, is less thermally stable than the metal silicide of the first area, and therefore is more likely to rupture upon application of a programming voltage.

In a sixth embodiment, an eFuse has a resistor formed on an insulator substrate having a layer of silicon germanium thereon. An outer portion of the resistor is formed of silicon and an inner portion is formed of metal silicide germanium. A metal silicide layer is provided over the silicon areas, defining a first area of metal silicide on silicon and a second area of metal silicide germanium on silicon germanium. The metal silicide germanium of the second area is less thermally stable than the metal silicide of the first area, and therefore is more likely to rupture upon application of a programming voltage.

The eFuses of the present invention provide for more reliable and predictable programming. In addition, the eFuses can be programmed with lower voltages due to the area of lower thermal stability.

### BRIEF DESCRIPTION OF THE DRAWINGS

The objects, features, and advantages of the invention will be apparent from the following more detailed description of certain embodiments of the invention and as illustrated in the accompanying drawings in which:

FIG. 1 is a top plan view of an eFuse in accordance with a first embodiment of the invention;

FIG. 2A is a cross-sectional view of the eFuse of FIG. 1; FIG. 2B illustrates the dimensions of the second area of the resistor shown in FIG. 2A;

FIG. 3 is a top plan view of an eFuse in accordance with a second embodiment of the invention;

FIG. 4 is a cross-sectional view of the eFuse of FIG. 3;

FIG. 5 is a top plan view of an eFuse in accordance with a third embodiment of the invention;

FIG. 6 is a cross-sectional view of the eFuse of FIG. 5;

FIG. 7 is a top plan view of an eFuse in accordance with a fourth embodiment of the invention;

FIG. 8 is a cross-sectional view of the eFuse of FIG. 7;

FIG. 9 is a top plan view of an eFuse in accordance with a fifth embodiment of the invention;

FIG. 10 is a cross-sectional view of the eFuse of FIG. 9;

FIG. 11 is a top plan view of an eFuse in accordance with a sixth embodiment of the invention; and

FIG. 12 is a cross-sectional view of the eFuse of FIG. 11.

### DETAILED DESCRIPTION OF THE INVENTION

It is noted that various connections are set forth between elements in the following description. It is noted that these connections in general and, unless specified otherwise, may be direct or indirect and that this specification is not intended to be limiting in this respect.

The eFuses of the present invention can be used in a variety of applications, non-limiting examples of which include silicon-on-insulator complementary metal oxide semiconductor large system integration (SOI CMOS LSI) devices, bulk CMOS LSI devices, programmable read-only memories (PROMs), field-programmable gate arrays (FPGAs), programmable array logic (PAL) devices, and very large system integration (VLSI) chips with SRAM and/or DRAM.

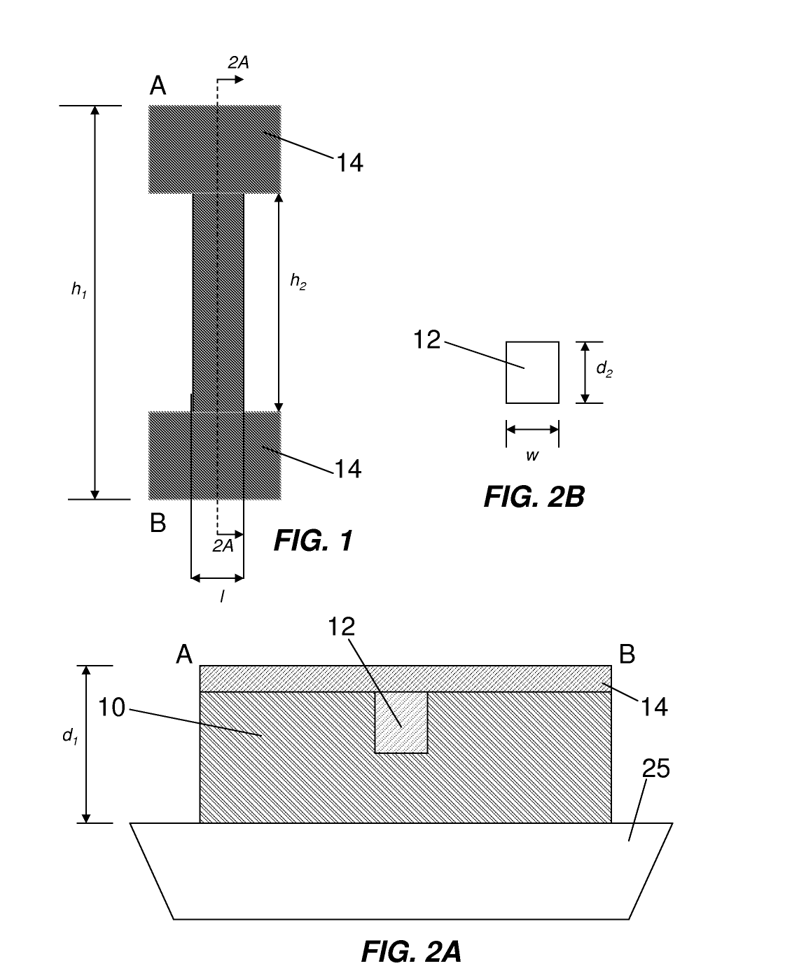

FIGS. 1 and 2A show top plan and cross-sectional views, respectively, of an eFuse according to a first embodiment of the invention. The eFuse has a resistor formed on a shallow trench isolation (STI) substrate 25. The resistor has an outer portion 10 formed of polysilicon and an inner portion 12 formed of polysilicon germanium (poly-Si₍₁₋ₓ₎Geₓ). The resistor also includes a metal silicide layer 14 over the outer 10 and inner 12 portions, defining a first area of nickel silicide on polysilicon and a second area of nickel silicide germanium (NiSi_{(1-y)}Ge_{y}) on polysilicon germanium, respectively.

As an alternative to nickel silicide (NiSiₓ), the metal silicide layer 14 can be selected from a number of types of other metal silicides, non-limiting examples of which include cobalt silicide (CoSiₓ), titanium silicide (TiSiₓ), palladium silicide (PdSiₓ), platinum silicide (PtSiₓ), ytterbium silicide (YbSiₓ), and erbium silicide (ErSiₓ), where x is 0.3 to 2.

As the term is used herein, an area is considered to be “embedded” in another area when its surface area is wholly or partially contained within the other area. For example, in the embodiment shown in FIG. 2, the second area (defined by inner portion of polysilicon germanium 12 and overlying portion of metal silicide 14) has a rectangular cross-section of which three sides contact the first area (defined by polysilicon 10 and overlying portion of metal silicide 14). In the embodiment of FIG. 6, discussed more fully below, the second area (defined by inner portion 32) has a rectangular cross-section of which two sides contact the first area (defined by outer portion 24). Other variations can be made without departing from the spirit of scope of the invention. For example, the second area may have a non-rectangular cross section having one or more of its surfaces contained within the first area.

Because the material of the second area is less thermally stable than the material of the first area, the second area is more likely to rupture when a programming voltage is applied. In the metal silicide layer 14 of the embodiment shown in FIGS. 1-2, for example, nickel silicide germanium (NiSi_{(1-y)}Ge_{y}) present in the inner portion is less thermally stable than nickel silicide present in the outer portions. The lower thermal stability of the nickel silicide germanium material also enables the eFuse to rupture at lower programming voltages. Effective programming voltages typically range from about 1.8 to 2.5 V, as compared to 3.3 V typical of conventional eFuses. Another benefit is that one can reliably predict the location at which the eFuse will rupture, namely in the second area due to its lower thermal stability.

With reference to FIG. 1, exemplary dimensions of the resistor include a total length h₁ of 200 to 5000 nm. The fuse length h₂ may be from 100 to 1500 nm and the fuse width 1 from 10 to 150 nm. With reference to FIG. 2A, the depth of the resistor d, may be from 30 to 200 nm. With reference to FIG. 2B, the embedded second area 12 may have a length w of about 20-200 nm and a depth d₂ of about 10-100 nm. The width of the second area 12 can be the same as the fuse width 1. It should be recognized that these dimensions are exemplary and not limiting. The actual dimensions of the eFuse and/or its components may vary from the exemplary dimensions given.

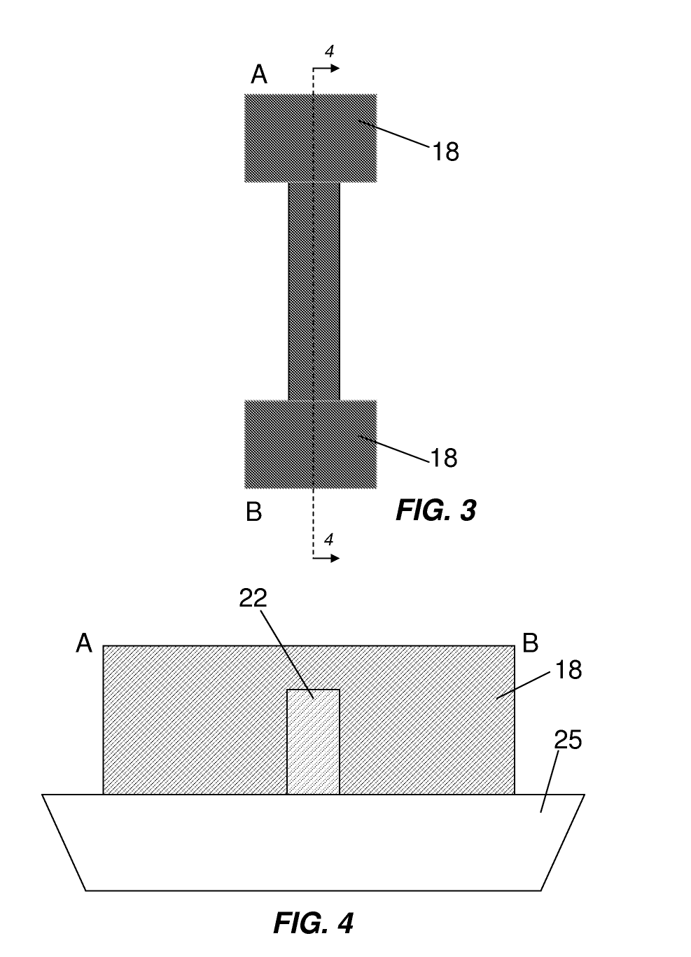

FIGS. 3 and 4 illustrate an eFuse in accordance with a second embodiment of the invention utilizing a fully silicided (FUSI) gate. The eFuse has a resistor formed on an STI substrate 25. The resistor has an outer portion of metal silicide, such as nickel silicide 18 (NiSi), and an inner portion of polysilicon 22 formed on the substrate 25 and extending less than the full depth of the nickel silicide 18 layer. The first area is defined by the thicker portions of the nickel silicide 18, while the second area is defined by the thinner portion of the nickel silicide 18 overlying the polysilicon 22. The depth of the nickel silicide in the thin portion can range from about 10-100 nm, for example. This thin layer of NiSi is less thermally stable than the thicker NiSi portions in the adjacent areas because thin NiSi layers tend to agglomerate. Therefore, the second area is more likely to rupture than the first area upon application of a programming voltage.

The eFuse of the second embodiment can be manufactured using the following steps. After gate electrode patterning and source/drain formation using a conventional CMOS process, the gate polysilicon is fully silicided by sputtered excessive Ni metal. This structure is known as FUSI. During FUSI formation, if a thin silicon oxide layer is present on top of the poly gate, NiSi growth is inhibited. In this embodiment, the thin layer of NiSi is generated only on the portion with the thin silicon oxide layer.

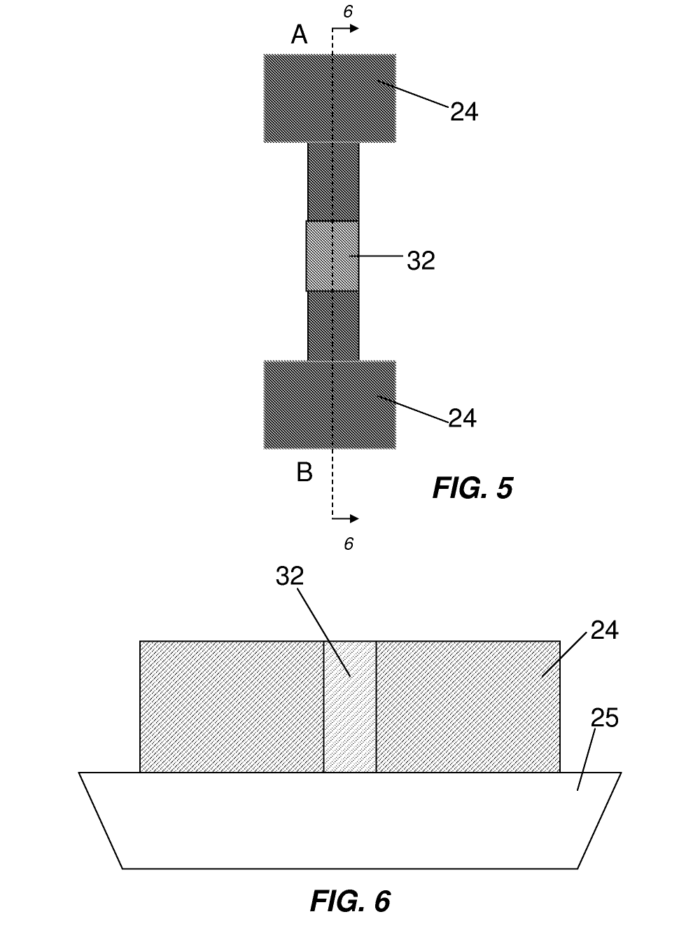

FIGS. 5 and 6 illustrate an eFuse in accordance with a third embodiment of the invention. The eFuse has a two-metal resistor formed on an STI substrate 25. The resistor has an outer portion of a first metal, such as cobalt silicide 24 (CoSi₂), and an inner portion of a second metal, such as nickel silicide 32. The first area is defined by the cobalt silicide 24, while the second area is defined by the nickel silicide 32. The thin nickel silicide 32 inner portion is less thermally stable than the thicker cobalt silicide 24 outer portion. Therefore, the nickel silicide 32 is more likely to rupture than the cobalt silicide 24 upon application of a programming voltage. Non-limiting examples of other combinations of first and second metals that can be used include NiSi₂ and Ni₃Si; W and NiSi; TiN and NiSi; and TaC and NiSi, respectively.

The eFuse of the third embodiment can be manufactured using a dual metal gate process with a replacement gate. This process is similar to FUSI except that this process uses two types of metal. One portion of a dummy poly gate is replaced with the first metal (e.g., area 24 in FIG. 6), while another portion of the dummy poly gate is protected from the replacement using a hard mask (e.g., area 32 in FIG. 6). After formation of the first metal 24, the remaining dummy poly gate is fully silicided to form the second metal 32.

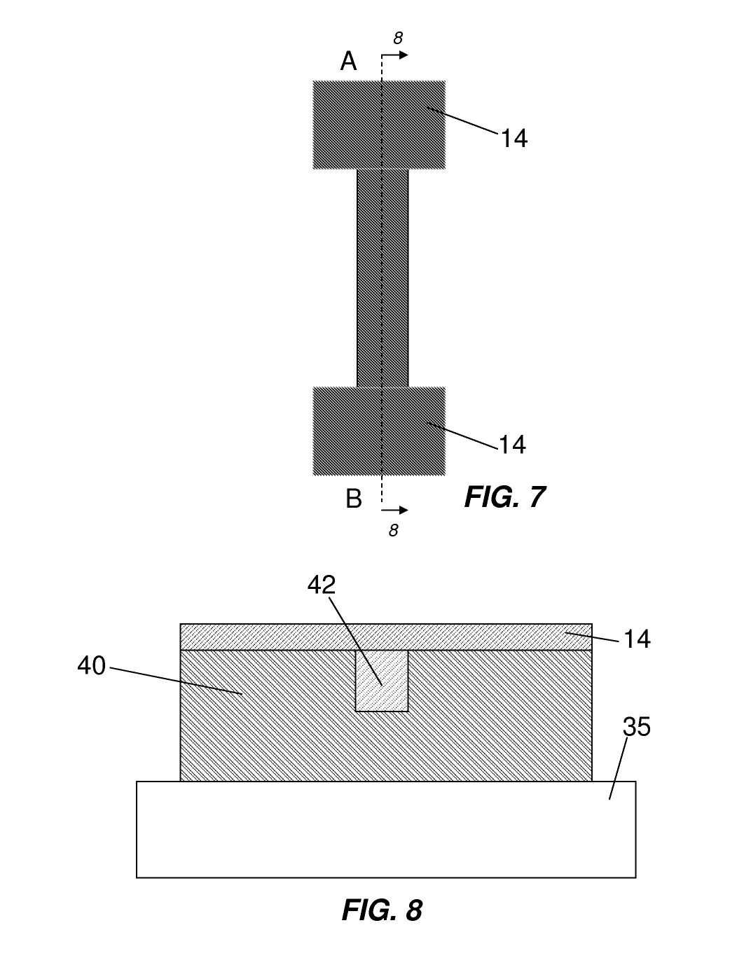

FIGS. 7 and 8 show top plan and cross-sectional views, respectively, of an eFuse according to a fourth embodiment of the invention. The resistor is prepared on a silicon-on-insulator (SOI) substrate 35. The insulator can be, for example, silicon dioxide (SiO₂). The resistor includes an outer portion 40 formed of silicon and an inner portion 42 formed of silicon germanium (Si₍₁₋ₓ₎Geₓ). The inner portion may have a length of about 20-200 nm and a depth of about 10-100 nm, for example. A metal silicide layer 14 is provided over the outer 40 and inner 42 portions. When nickel silicide is used as the metal silicide, the first area includes nickel silicide on silicon and the second area includes nickel silicide germanium (NiSi_{(1-y)}Ge_{y}) on silicon germanium. NiSi_{(1-y)}Ge_{y} of the second area is less thermally stable than NiSi of the first area, and therefore is more likely to rupture upon application of a programming voltage.

The structure of the fourth embodiment can be manufactured by embedded SiGe source/drain, which is now commercially used in the advanced CMOS process. An SOI substrate can be etched away in portion 42, followed by selective epitaxial growth of silicon germanium. The portion 40 can be protected from this etching and selective SiGe growth using conventional techniques.

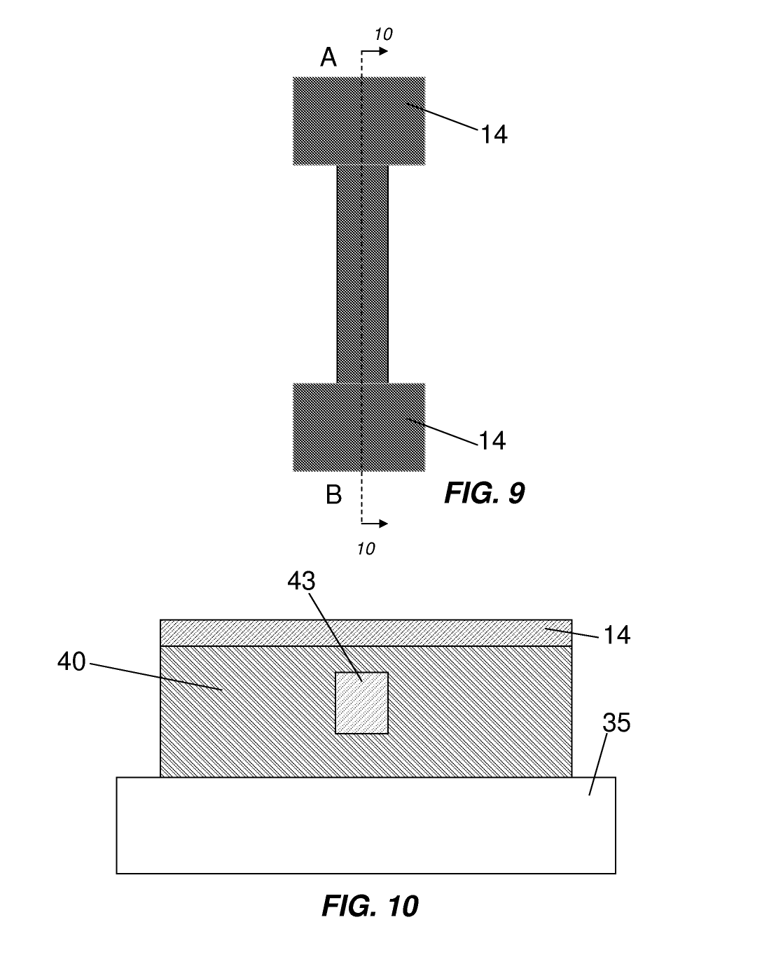

FIGS. 9 and 10 show top plan and cross-sectional views, respectively, of an eFuse according to a fifth embodiment of the invention. The resistor is formed on a silicon-on-insulator (SOI) substrate 35. The resistor includes an outer portion 40 formed of silicon and an inner portion 43 formed of silicon germanium (Si₍₁₋ₓ₎Geₓ) that is entirely surrounded by the silicon portion 40. The inner portion 43 may have a length of about 20-200 nm and a depth of about 10-100 nm, for example. The thickness of the silicon in the area above the inner portion 43 can be from about 5 to about 30 nm. A layer 14 of metal silicide, such as nickel silicide, is provided over the silicon 40, defining a first area of nickel silicide on silicon and a second area of nickel silicide on silicon on silicon germanium (Si₍₁₋ₓ₎Geₓ). NiSi of the second area, which has silicon germanium underneath, is less thermally stable than NiSi of the first area, and is more likely to rupture upon application of a programming voltage.

The eFuse of the embodiment shown in FIGS. 9 and 10 can be manufactured using commercially available substrates having five layers of silicon, oxide, silicon, silicon germanium, and single crystal silicon. The eFuse of this embodiment can be manufactured using steps similar to those described above for the fourth embodiment, with the difference being that selective SiGe epitaxial growth is followed by Si epitaxial growth.

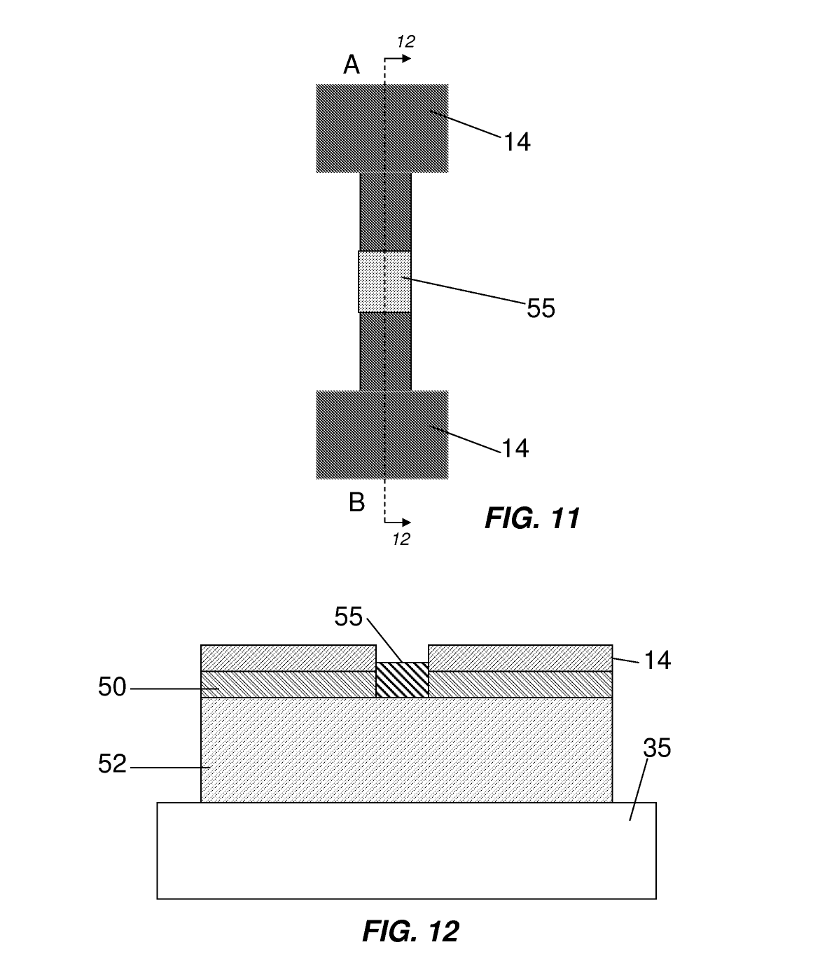

FIGS. 11 and 12 show top plan and cross-sectional views, respectively, of an eFuse according to a sixth embodiment of the invention. The resistor is formed on an insulator substrate 35. A layer of silicon germanium 52 is provided on the substrate 35. An outer portion 50 is formed of silicon and an inner portion 55 is formed of nickel silicide germanium (NiSi_{(1-y)}Ge_{y}). The inner portion can have a length of about 20-200 nm and a depth of about 10-100 nm. A metal silicide layer 14 is provided over the silicon areas 50, defining a first area of nickel silicide on silicon and a second area of nickel silicide germanium (NiSi_{(1-y)}Ge_{y}) on silicon germanium. NiSi_{(1-y)}Ge_{y} of the second area is less thermally stable than NiSi of the first area, and therefore is more likely to rupture upon application of a programming voltage.

The eFuse of the embodiment shown in FIGS. 11 and 12 can be manufactured using commercially available substrates, SGOI substrates, having five layers of silicon, silicon oxide, silicon, silicon germanium, and single crystal silicon on top. The eFuse of this embodiment can be manufactured by Si-etching portion 55, followed by a conventional CMOS process, which includes a Ni SALICIDE process. Following the salicidation process, NiSi_{(1-y)}Ge_{y} can be generated over the SiGe layer, and NiSi can be generated over the Si layer.

While particular embodiments of the present invention have been described and illustrated, it should be understood that the invention is not limited thereto since modifications may be made by persons skilled in the art. The present application contemplates any and all modifications that fall within the spirit and scope of the underlying invention disclosed and claimed herein.

What is claimed is:

1. An electrical fuse comprising a resistor formed on a substrate;
wherein the resistor comprises a first material defining a first area and a second material defining a second area, wherein the second area is embedded in the first area; and
wherein the first material has a first thermal stability and the second material has a second thermal stability which is less than the first thermal stability.

2. The electrical fuse of claim 1 wherein the first material comprises metal silicide on polysilicon and wherein the second material comprises metal silicide on polysilicon germanium.

3. The electrical fuse of claim 2 wherein the metal silicide is selected from the group consisting of NiSiₓ, CoSiₓ, TiSiₓ, PdSiₓ, PtSiₓ, YbSiₓ, and ErSiₓ, where x is 0.3 to 2.

4. The electrical fuse of claim 1 wherein the first material comprises metal silicide and the second material comprises metal silicide on polysilicon.

5. The electrical fuse of claim 4 wherein the metal silicide is selected from the group consisting of NiSiₓ, CoSiₓ, TiSiₓ, PdSiₓ, PtSiₓ, YbSiₓ, and ErSiₓ, where x is 0.3 to 2.

6. The electrical fuse of claim 1 wherein the first material is NiSi and the second material is CoSi₂.

7. The electrical fuse of claim 1 wherein the first material is NiSi₂ and the second material is Ni₃Si.

8. The electrical fuse of claim 1 wherein the first material is W and the second material is NiSi.

9. The electrical fuse of claim 1 wherein the first material is TiN and the second material is NiSi.

10. The electrical fuse of claim 1 wherein the first material is TaC and the second material is NiSi.

11. The electrical fuse of claim 1 wherein the substrate comprises silicon-on-insulator and wherein the first material is metal silicide on silicon and the second material is metal silicide germanium on silicon germanium.

12. The electrical fuse of claim 11 wherein the metal silicide is selected from the group consisting of NiSiₓ, CoSiₓ, TiSiₓ, PdSiₓ, PtSiₓ, YbSiₓ, and ErSiₓ, where x is 0.3 to 2.

13. The electrical fuse of claim 1 wherein the substrate comprises silicon-on-insulator and wherein the first material is metal silicide on silicon and the second material is metal silicide on silicon on silicon germanium.

14. The electrical fuse of claim 13 wherein the metal silicide is selected from the group consisting of NiSiₓ, CoSiₓ, TiSiₓ, PdSiₓ, PtSiₓ, YbSiₓ, and ErSiₓ, where x is 0.3 to 2.

15. The electrical fuse of claim 1 wherein the substrate comprises silicon germanium on insulator and wherein the first material is metal silicide on silicon and the second material is metal silicide germanium.

16. The electrical fuse of claim 15 wherein the metal silicide is selected from the group consisting of NiSiₓ, CoSiₓ, TiSiₓ, PdSiₓ, PtSiₓ, YbSiₓ, and ErSiₓ, where x is 0.3 to 2.

17. A silicon-on-insulator complementary metal oxide semiconductor large system integration (SOI CMOS LSI) device comprising the electrical fuse of claim 1.

18. A bulk complementary metal oxide semiconductor large system integration (CMOS LSI) device comprising the electrical fuse of claim 1.
